(19) United States
(12) Patent Application Publication
(10) Pub. No.: US 2026/0260675 A1
(43) Pub. Date: Sep. 3, 2026

(54) SEMICONDUCTOR APPARATUS PERFORMING OFFSET CALIBRATION

(71) Applicant: SK hynix Inc., Icheon-si Gyeonggi-do (KR)

(72) Inventors: Gyeong Ha RYU, Icheon-si Gyeonggi-do (KR); Bo Ram KIM, Icheon-si Gyeonggi-do (KR)

(73) Assignee: SK hynix Inc., Icheon-si Gyeonggi-do (KR)

(21) Appl. No.: 19/237,346

(22) Filed: Jun. 13, 2025

(30) Foreign Application Priority Data
Feb. 28, 2025 (KR) 10-2025-0026779

(51) Int. Cl. G11C 7/10; G11C 5/14; G11C 7/22

(52) U.S. Cl. CPC G11C 7/1051; G11C 5/147; G11C 7/1078; G11C 7/222; G11C 2207/2254

(57) ABSTRACT

A semiconductor apparatus includes a calibration control circuit, a first data input and output block, and a second data input and output block. The calibration control circuit generates a main clock signal and a calibration control signal for an offset calibration operation. The first data input and output block adjusts the offset of the first data input and output block based on the main clock signal, the calibration control signal, and a reference voltage. The second data input and output block adjusts the offset of the second data input and output block based on the main clock signal, the calibration control signal, and the reference voltage.

### CROSS-REFERENCE TO RELATED APPLICATION

The present application claims priority under 35 U.S.C. § 119 (a) to Korean Patent Application No. 10-2025-0026779, filed in the Korean Intellectual Property Office on Feb. 28, 2025, the entire contents of which application is incorporated herein by reference.

### BACKGROUND

### 1. Technical Field

The present disclosure relates to integrated circuits, including but not limited to a semiconductor apparatus performing offset calibration.

### 2. Related Art

An electronic device includes many electronic components. Among the electronic components, a computing system may include many semiconductor apparatus composed of semiconductors. The semiconductor apparatus that constitute the computing system may communicate with each other by transmitting and receiving clock signals, data signals, and various control signals. A differential signal or a single-ended signal may be used in the transmission of signals between the semiconductor apparatus. Each semiconductor apparatus may include a reception circuit that receives the differential signal or the single-ended signal. The reception circuit may receive the differential signal and the single-ended signal by differentially amplifying the differential signal or differentially amplifying the single-ended signal and a reference voltage.

A mismatch may occur between transistors included in the reception circuit due to process variation. The offset of the reception circuit may occur due to the mismatch. As the speed of the computing system increases, the frequency of a clock signal increases, and the amplitude and/or signal swing of various signals that are transmitted between the semiconductor apparatuses decreases. If the amplitude and/or signal swing of the signals is sufficiently great, the offset of the reception circuit might not be a problem in receiving the signals. Distortion may occur in a signal received through the reception circuit, and the bit error rate may increase because the ratio of the offset of the reception circuit to the amplitude and/or signal swing of the signals gradually increases as the amplitude and/or signal swing of the signals decreases. Accordingly, the semiconductor apparatus each adopt offset calibration that corrects the offset of the reception circuit. In the computer industry, various semiconductor apparatus product groups are present, and various computing systems may be constructed using a combination of product groups.

### SUMMARY

In an embodiment, a semiconductor apparatus may include a calibration control circuit, a first data input and output block, a second data input and output block, a first reference voltage generation circuit, a second reference voltage generation circuit, and a third reference voltage generation circuit. The calibration control circuit may be configured to generate a main clock signal, a calibration control signal, and a reference voltage control signal based on an offset calibration signal. The first data input and output block may be configured to generate a first group of reception signals based on a first data signal and a reference voltage and configured to adjust an offset of the first data input and output block based on the main clock signal and the calibration control signal. The second data input and output block may be configured to generate a second group of reception signals based on a second data signal and the reference voltage and configured to adjust an offset of the second data input and output block based on the main clock signal and the calibration control signal. The first reference voltage generation circuit may be configured to generate the reference voltage based on the reference voltage control signal. The second reference voltage generation circuit may be configured to generate the reference voltage based on the reference voltage control signal. The third reference voltage generation circuit may be configured to generate the reference voltage based on the reference voltage control signal.

In an embodiment, a semiconductor apparatus may include a data reception circuit and a reference voltage generation circuit. The data reception circuit may be configured to generate a reception signal by comparing a data signal and a reference voltage based on a calibration clock signal. The reference voltage generation circuit may be configured to generate the reference voltage at different voltage levels based on an operation mode.

The data reception circuit may include a first node, a second node, a receiver, and a calibration setting circuit. The data signal may be input on the first node. The receiver may be configured to generate the reception signal by differentially amplifying a voltage level of the first node and a voltage level of the second node in synchronization with the calibration clock signal. The calibration setting circuit may be configured to, based on the operation mode, selectively electrically couple the first node to ground, to selectively electrically couple the first node to the second node, to selectively electrically couple the second node to ground, and to selectively provide the reference voltage to the second node.

In an embodiment, a semiconductor may include a reference voltage generation circuit and a data reception circuit. The reference voltage generation circuit may be configured to generate the reference voltage at a voltage level based on an operation mode. The data reception circuit may include a receiver configured to generate a reception signal, in synchronization with a calibration clock signal, by differentially amplifying a voltage level of a second node and a voltage level of a first node coupled to a data signal; and a calibration setting circuit configured to, based on the operation mode, selectively couple the first node to at least one of ground and the second node and selectively couple the second node to one of ground and the reference voltage.

### BRIEF DESCRIPTION OF THE DRAWINGS

FIG. 1 is a diagram illustrating a construction of a semiconductor apparatus according to an embodiment.

FIG. 2 is a diagram illustrating a connection relation between data reception circuits included in a first data input and output block according to an embodiment.

FIG. 3 is a diagram illustrating a construction of a first data reception circuit according to an embodiment.

FIG. 4A to FIG. 4D are diagrams illustrating signal states of a first data reception circuit according to an embodiment.

FIG. 5 is a diagram illustrating a construction of a receiver according to an embodiment.

FIG. 6 is a diagram illustrating a construction of a calibration clock generation circuit according to an embodiment.

FIG. 7 is a timing diagram illustrating offset calibration operation of the semiconductor apparatus according to an embodiment.

FIG. 8 is a diagram illustrating a construction of a semiconductor system according to an embodiment.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “first” and “second” are used to distinguish between various elements and do not imply size, order, priority, quantity, or importance of the elements. For example, a first element may be referred to as a second element in one example, and the second element may be referred to as a first element in another example.

When one element is identified as “coupled” to another element, the elements may be coupled directly or through at least one intervening element between the elements. When two elements are identified as “directly coupled,” one element is directly coupled to the other element without an intervening element between the two elements.

The terms “enable” and “disable” with reference to a signal include generating the signal at a first voltage level to enable the signal and at a second first voltage level to disable the signal. For example, the first voltage level may be a logic high level and the second voltage level may be a logic low level.

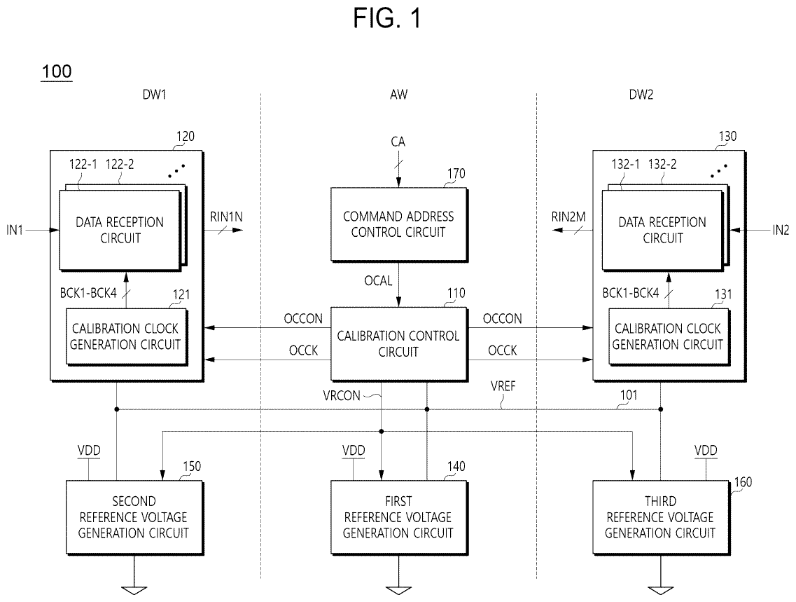

FIG. 1 is a diagram illustrating a construction of a semiconductor apparatus 100 according to an embodiment. The semiconductor apparatus 100 receives signals transmitted by an external device. The signals transmitted by the external device include a command address signal CA, a data signal, and a clock signal. The semiconductor apparatus 100 includes reception circuits that receive the data signal. The semiconductor apparatus 100 adjusts the offsets of the reception circuits by performing offset calibration operation. The semiconductor apparatus 100 includes a first region AW, a second region DW1, and a third region DW2. The second region DW1 is adjacent to a first side of the first region AW, such as the left side of the first region AW in FIG. 1. The third region DW2 is adjacent to a second side of the first region AW, such as the right side of the first region AW in FIG. 1. The second region DW1 is closer to the first region AW than to the third region DW2. The third region DW2 is closer to the first region AW than to the second region DW1. Internal circuits of the semiconductor apparatus 100, which receive the command address signal CA and the clock signal except for the data signal, are disposed in the first region AW. Internal circuits of the semiconductor apparatus 100, which receive the data signal, are disposed in the second region DW1 and the third region DW2.

The semiconductor apparatus 100 includes a calibration control circuit 110, a first data input and output block 120, a second data input and output block 130, a first reference voltage generation circuit 140, a second reference voltage generation circuit 150, and a third reference voltage generation circuit 160. The calibration control circuit 110 and the first reference voltage generation circuit 140 are disposed in the first region AW. The first data input and output block 120 and the second reference voltage generation circuit 150 are disposed in the second region DW1. The second data input and output block 130 and the third reference voltage generation circuit 160 are disposed in the third region DW2. A distance between the first reference voltage generation circuit 140 and the second reference voltage generation circuit 150 may be substantially the same as a distance between the second reference voltage generation circuit 150 and the third reference voltage generation circuit 160, although distances between the circuits may be different. A distance between the second reference voltage generation circuit 150 and the first data input and output block 120 may be substantially the same as or may be different from a distance between the third reference voltage generation circuit 160 and the second data input and output block 130.

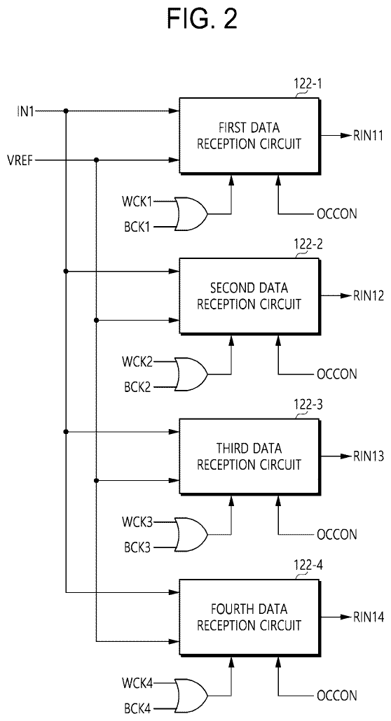

The calibration control circuit 110 receives an offset calibration signal OCAL and controls the data input and output blocks 120 and 130 to perform offset calibration operations. The calibration control circuit 110 generates a main clock signal OCCK and a calibration control signal OCCON based on the offset calibration signal OCAL. The calibration control circuit 110 generates the main clock signal OCCK when the offset calibration signal OCAL is enabled. The calibration control circuit 110 includes an oscillating circuit (not illustrated) and generates the main clock signal OCCK using the oscillating circuit. The oscillating circuit is activated when the offset calibration signal OCAL is enabled and generates the main clock signal OCCK. The frequency and/or cycle of the main clock signal OCCK may vary. The frequency of the main clock signal OCCK may be lower than the frequency of a clock signal that is received by the semiconductor apparatus 100 from an external device. The main clock signal may have a lower frequency than a write clock signal described with respect to FIG. 2. The calibration control circuit 110 selects an operation mode for data reception circuits included in the data input and output blocks 120 and 130 when the offset calibration signal OCAL is enabled. To select the operation mode, the calibration control circuit 110 generates the calibration control signal OCAL and provides the calibration control signal OCCON to the data input and output blocks 110 and 120. The calibration control signal OCCON includes various logic values utilized to select the operation mode. The calibration control circuit 110 generates a reference voltage control signal VRCON to select the operation mode. The calibration control circuit 110 provides the reference voltage control signal VRCON to the reference voltage generation circuits 140, 150, and 160.

The semiconductor apparatus 100 includes a command address control circuit 170. The command address control circuit 170 receives the command address signal CA from the device external to the semiconductor apparatus 100 and generates the offset calibration signal OCAL based on a command address signal CA. When the external device provides the semiconductor apparatus 100 with the command address signal CA indicating or initiating execution of offset calibration operation, the command address control circuit 170 enables the offset calibration signal OCAL by decoding the command address signal CA. When the external device provides the semiconductor apparatus 100 with the command address signal CA indicative of termination of offset calibration operation, the command address control circuit 170 disables the offset calibration signal OCAL. For example, after the semiconductor apparatus 100 is powered up, the external device provides the command address signal CA to initiate offset calibration operation during the training operation interval of the semiconductor apparatus 100. The training operation includes operations that select and calibrate various operation parameters of the semiconductor apparatus 100 such that the external device and the semiconductor apparatus 100 can perform smooth or accurate data communication.

The first data input and output block 120 receives a first data signal IN1, a reference voltage VREF, the main clock signal OCCK, and the calibration control signal OCCON. The first data input and output block 120 generates a first group of reception signals RIN1N based on the first data signal IN1 and the reference voltage VREF during a normal operation, where N is an integer greater than 1. Normal operation includes an operation in which the data input and output blocks 120 and 130 receive the first and second data signals IN1 and IN2, respectively. For example, the normal operation may be performed after offset calibration operation is completed. The first data input and output block 120 adjusts the offset of the first data input and output block 120 based on the main clock signal OCCK and the calibration control signal OCCON during offset calibration operation. The first data input and output block 120 individually adjusts the offsets of data reception circuits included in the first data input and output block 120. The first data input and output block 120 generates a plurality of calibration clock signals based on the main clock signal OCCK.

The first data input and output block 120 may include a calibration clock generation circuit 121 and a plurality of data reception circuits 122-1, 122-2, 122-3, 122-4. The quantity of data reception circuits may vary. The calibration clock generation circuit 121 receives the main clock signal OCCK and generates a plurality of calibration clock signals from the main clock signal OCCK. The quantity of the plurality of calibration clock signals generated by the calibration clock generation circuit 121 may be substantially the same as the quantity of the plurality of data reception circuits. The quantity of data reception circuits included in the first data input and output block 120 may be a multiple of 2. For example, when the first data input and output block 120 includes four data reception circuits, the calibration clock generation circuit 121 generates four calibration clock signals. The calibration clock generation circuit 121 generates a first calibration clock signal BCK1, a second calibration clock signal BCK2, a third calibration clock signal BCK3, and a fourth calibration clock signal BCK4, each based on the main clock signal OCCK. The calibration clock generation circuit 121 counts a characteristic of the main clock signal OCCK, for example, a rising edge or falling edge of the main clock signal OCCK, and sequentially generates the first calibration clock signal BCK1, the second calibration clock signal BCK2, the third calibration clock signal BCK3, and the fourth calibration clock signal BCK4 based on the count.

FIG. 2 is a diagram illustrating a connection relation between data reception circuits included in the first data input and output block 120, for example, as illustrated in FIG. 1. Referring to FIG. 2, the first data input and output block 120 includes a first data reception circuit 122-1, a second data reception circuit 122-2, a third data reception circuit 122-3, and a fourth data reception circuit 122-4. A first group of reception signals RIN1N generated by the first data input and output block 120 includes a first reception signal RIN11, a second reception signal RIN12, a third reception signal RIN13, and a fourth reception signal RIN14, where N is an integer greater than 1. The first data reception circuit 122-1 receives the first data signal IN1, the reference voltage VREF, the first calibration clock signal BCK1, and the calibration control signal OCCON. The first data reception circuit 122-1 generates the first reception signal RIN11 based on the first data signal IN1 and the reference voltage VREF during normal operation. The first data reception circuit 122-1 receives a first write clock signal WCK1. The first data reception circuit 122-1 generates the first reception signal RIN11 by comparing the first data signal IN1 and the reference voltage VREF in synchronization with the first write clock signal WCK1. The first data reception circuit 122-1 adjusts the offset of the first data reception circuit 122-1 based on the first calibration clock signal OCCK and the calibration control signal OCCON during offset calibration operation. The first data reception circuit 122-1 selects the operation mode of the first data reception circuit 122-1 based on the calibration control signal OCCON and performs calibration on the offset of the first data reception circuit 122-1 in synchronization with the first calibration clock signal BCK1.

The second data reception circuit 122-2 receives the first data signal IN1, the reference voltage VREF, the second calibration clock signal BCK2, and the calibration control signal OCCON. The second data reception circuit 122-2 generates the second reception signal RIN12 based on the first data signal IN1 and the reference voltage VREF during the normal operation. The second data reception circuit 122-2 receives a second write clock signal WCK2. The second data reception circuit 122-2 generates the second reception signal RIN12 by comparing the first data signal IN1 and the reference voltage VREF in synchronization with the second write clock signal WCK2. The second data reception circuit 122-2 adjusts the offset of the second data reception circuit 122-2 based on the second calibration clock signal BCK2 and the calibration control signal OCCON during offset calibration operation. The second data reception circuit 122-2 selects the operation mode of the second data reception circuit 122-2 based on the calibration control signal OCCON and performs calibration on the offset of the second data reception circuit 122-2 in synchronization with the second calibration clock signal BCK2.

The third data reception circuit 122-3 receives the first data signal IN1, the reference voltage VREF, the third calibration clock signal BCK3, and the calibration control signal OCCON. The third data reception circuit 122-3 generates the third reception signal RIN13 based on the first data signal IN1 and the reference voltage VREF during normal operation. The third data reception circuit 122-3 receives a third write clock signal WCK3. The third data reception circuit 122-3 generates the third reception signal RIN13 by comparing the first data signal IN1 and the reference voltage VREF in synchronization with the third write clock signal WCK3. The third data reception circuit 122-3 adjusts the offset of the third data reception circuit 122-3 based on the third calibration clock signal BCK3 and the calibration control signal OCCON during offset calibration operation. The third data reception circuit 122-3 selects the operation mode of the third data reception circuit 122-3 based on the calibration control signal OCCON and performs calibration on the offset of the third data reception circuit 122-3 in synchronization with the third calibration clock signal BCK3.

The fourth data reception circuit 122-4 receives the first data signal IN1, the reference voltage VREF, the fourth calibration clock signal BCK4, and the calibration control signal OCCON. The fourth data reception circuit 122-4 generates the fourth reception signal RIN14 based on the first data signal IN1 and the reference voltage VREF during normal operation. The fourth data reception circuit 122-4 receives a fourth write clock signal WCK4. The fourth data reception circuit 122-4 generates the fourth reception signal RIN14 by comparing the first data signal IN1 and the reference voltage VREF in synchronization with the fourth write clock signal WCK4. The fourth data reception circuit 122-4 adjusts the offset of the fourth data reception circuit 122-4 based on the fourth calibration clock signal BCK4 and the calibration control signal OCCON during offset calibration operation. The fourth data reception circuit 122-4 selects the operation mode of the fourth data reception circuit 122-4 based on the calibration control signal OCCON and performs calibration on the offset of the fourth data reception circuit 122-4 in synchronization with the fourth calibration clock signal BCK4.

Referring to FIG. 1, the semiconductor apparatus 100 generates the write clock signals WCK1, WCK2, WCK3, and WCK4 by dividing a clock signal transmitted by the external device during normal operation. For example, the clock signal may be transmitted to the data input and output blocks 120 and 130. The data input and output blocks 120 and 130 generate the first write clock signal WCK1, the second write clock signal WCK2, the third write clock signal WCK3, and the fourth write clock signal WCK4 by dividing the clock signal. The write clock signals WCK1, WCK2, WCK3, and WCK4 sequentially have a phase difference of 90 degrees, for example, 90 degree phase difference between write clock signals WCK1 and WCK2, 90 degree phase difference between write clock signals WCK2 and WCK3, and so forth, and may each have a longer cycle than the clock signal. As described, the calibration clock signals BCK1, BCK2, BCK3, and BCK4 have longer cycles than the write clock signals WCK1, WCK2, WCK3, and WCK4, respectively.

Referring to FIG. 1, the second data input and output block 130 receive the second data signal IN2, the reference voltage VREF, the main clock signal OCCK, and the calibration control signal OCCON. The second data input and output block 130 generates a second group of reception signals RIN2M based on the second data signal IN2 and the reference voltage VREF during normal operation, where M is an integer greater than 1. M may be substantially the same as N. The second data input and output block 130 adjusts the offset of the second data input and output block 130 based on the main clock signal OCCK and the calibration control signal OCCON during offset calibration operation. The second data input and output block 130 individually adjusts the offsets of data reception circuits included in the second data input and output block 130. The second data input and output block 130 generates a plurality of calibration clock signals based on the main clock signal OCCK. The second data input and output block 130 may have substantially the same configuration as the first data input and output block 120. The second data input and output block 130 includes a calibration clock generation circuit 131 and a plurality of data reception circuits 132-1, 132-2, The calibration clock generation circuit 131 generates the calibration clock signals BCK1, BCK2, BCK3, and BCK4 by performing substantially the same or similar operations as performed by the calibration clock generation circuit 121. The data reception circuits 132-1, 132-2, . . . may be configured similarly and perform substantially the same or similar operations as the data reception circuits 122-1, 122-2, 122-3, and 122-4 illustrated in FIG. 2.

The first reference voltage generation circuit 140 receives the reference voltage control signal VRCON and generates the reference voltage VREF based on the reference voltage control signal VRCON. The first reference voltage generation circuit 140 is electrically coupled to a power line 101 and outputs the reference voltage VREF to the power line 101. The first reference voltage generation circuit 140 generates the reference voltage VREF at different voltage levels based on whether the reference voltage control signal VRCON is enabled. For example, the first reference voltage generation circuit 140 generates the reference voltage VREF at one of a first voltage level and a second voltage level. When the reference voltage control signal VRCON is disabled, the first reference voltage generation circuit 140 generates the reference voltage VREF at the first voltage level. When the reference voltage control signal VRCON is enabled, the first reference voltage generation circuit 140 generates the reference voltage VREF at the second voltage level. The first voltage level is a voltage level corresponding to the middle of a range in which the first data signals IN1 and the second data signal IN2 vary. The second voltage level may have a higher voltage level than the first voltage level and may have a lower voltage level than the first voltage level. The first reference voltage generation circuit 140 includes, for example, a pull-up resistor and a pull-down resistor that are electrically coupled in series between a source voltage VDD and a ground voltage and generates the reference voltage VREF by changing the ratio of the resistance values of the pull-up resistor and the pull-down resistor. For example, when the reference voltage control signal VRCON is disabled, the first reference voltage generation circuit 140 generates the reference voltage VREF having a voltage level, for example, the first voltage level, corresponding to half the voltage level of the source voltage VDD when the ratio of the resistance values of the pull-up resistor and the pull-down resistor to 1:1. When the reference voltage control signal VRCON is enabled, the first reference voltage generation circuit 140 generates the reference voltage VREF at a higher voltage level than the first voltage level by increasing the ratio of the resistance value of the pull-down resistor or generates the reference voltage VREF at a lower voltage level than the first voltage level by increasing the ratio of the resistance value of the pull-up resistor.

The reference voltage generation circuits 150 and 160 may each perform substantially the same or similar operations as the first reference voltage generation circuit 140 as described with respect to FIG. 1. The reference voltage generation circuits 140, 150, and 160 are electrically coupled in common to the power line 101. Accordingly, the reference voltages VREF generated by the reference voltage generation circuits 140, 150, and 160 is supplied to the first data input and output block 120 and the second data input and output block 130 through the power line 101. In an embodiment, the semiconductor apparatus 100, the reference voltage generation circuits 140, 150, and 160 are distributed physically and disposed in the regions AW, DW1, and DW2, respectively. The voltage levels of the reference voltages VREF are received by the data input and output blocks 120 and 130 may be substantially identical with each other, resulting in equalized performance of the data input and output blocks 120 and 130 in an embodiment.

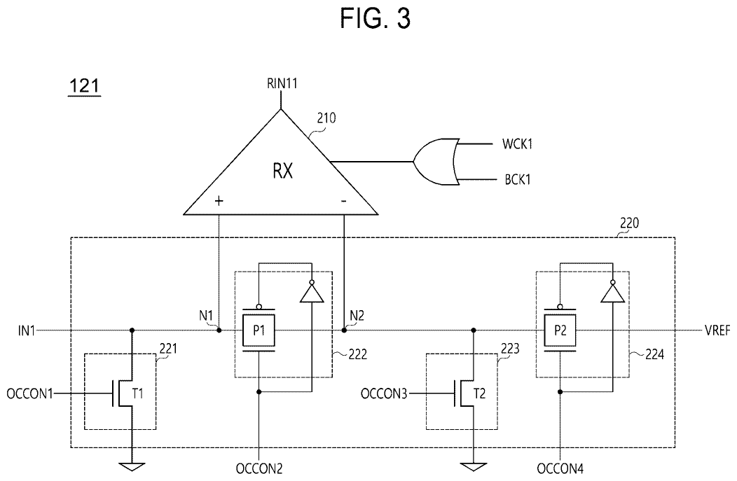

FIG. 3 is a diagram illustrating a construction of the first data reception circuit 122-1 according to an embodiment. Referring to FIG. 3, the first data reception circuit 122-1 includes a receiver (RX) 210 and a calibration setting circuit 220. The receiver 210 includes a first input terminal (+) to which a first node N1 is electrically coupled and a second input terminal (−) to which a second node N2 is electrically coupled. The first data signal IN1 is input to the first node N1. The receiver 210 generates the first reception signal RIN11 by differentially amplifying the voltage levels at the first node N1 and the second node N2. The receiver 210 performs an amplification operation in synchronization with the first write clock signal WCK1 and the first calibration clock signal BCK1. During normal operation, the receiver 210 generates the first reception signal RIN11 by differentially amplifying the voltage levels of the first and second nodes N1 and N2 in synchronization with the first write clock signal WCK1. During offset calibration operation, the receiver 210 generates the first reception signal RIN11 by differentially amplifying the voltage levels of the nodes N1 and N2 in synchronization with the first calibration clock signal BCK1.

The calibration setting circuit 220 varies the signal states of the nodes N1 and N2 depending or based on the operation mode. The calibration setting circuit 220 selectively electrically couples the first node N1 to ground, selectively electrically couples the first node N1 to the second node N2, selectively electrically couples the second node N2 to ground, and selectively provides the reference voltage VREF to the second node N2 based on the operation mode. The calibration setting circuit 220 does not electrically couple the nodes N1 and N2 to ground, does not electrically couple the first node N1 to the second node N2, and provides the reference voltage VREF to the second node N2 during normal operation. The calibration setting circuit 220 varies the signal states of the nodes N1 and N2 depending on the operation mode during offset calibration operation. When the operation mode is a first mode, the calibration setting circuit 220 electrically couples the first node N1 to ground, electrically couples the first node N1 to the second node N2, and electrically couples the second node N2 to ground. The calibration setting circuit 220 does not provide the second node N2 with the reference voltage VREF. When the operation mode is a second mode, the calibration setting circuit 220 does not electrically couple the first node to the second node N2 and electrically couples the first node N1 to the second node N2. The calibration setting circuit 220 provides the second node N2 with the reference voltage VREF. When the operation mode is a third mode, the calibration setting circuit 220 does not electrically couple the nodes N1 and N2 to ground and electrically couples the first node N1 to the second node N2. The calibration setting circuit 220 provides the second node N2 with the reference voltage VREF. When the operation mode is a fourth mode, the calibration setting circuit 220 electrically couples the first node N1 to ground, electrically couples the first node N1 to the second node N2, and does not electrically couple the second node N2 to ground. The calibration setting circuit 220 provides the second node N2 with the reference voltage VREF. The values of the calibration control signal OCCON are used to select one of the first mode to the fourth mode as the operation mode. The calibration setting circuit 220 sets the signal states of the nodes N1 and N2 based on the calibration control signal OCCON. The calibration control signal OCCON includes a first control signal OCCON1, a second control signal OCCON2, a third control signal OCCON3, and a fourth control signal OCCON4.

The calibration setting circuit 220 includes a first pull-down driver 221, a first switching circuit 222, a second pull-down driver 223, and a second switching circuit 224. The first pull-down driver 221 receives the first control signal OCCON1 and selectively electrically couples the first node N1 to ground based on the first control signal OCCON1. When the first control signal OCCON1 is enabled, the first pull-down driver 221 electrically couples the first node N1 to ground. When the first control signal OCCON1 is disabled, the first pull-down driver 221 isolates the first node N1 from ground. The first pull-down driver 221 includes a first transistor T1. The first transistor T1 may be an N channel MOS transistor. A gate of the first transistor T1 receives the first control signal OCCON1. A drain of the first transistor T1 is electrically coupled to the first node N1. A source of the first transistor T1 is electrically coupled to ground.

The first switching circuit 222 receive the second control signal OCCON2 and selectively electrically couples the first node N1 to the second node N2 based on the second control signal OCCON2. When the second control signal OCCON2 is enabled, the first switching circuit 222 electrically couples the first node N1 to the second node N2. When the second control signal OCCON2 is disabled, the first switching circuit 222 isolates the first node N1 from the second node N2. The first switching circuit 222 includes a first pass gate P1. One end of the first pass gate P1 is electrically coupled to the first node N1. The other end of the first pass gate P1 is electrically coupled to the second node N2. The first pass gate P1 receives the second control signal OCCON2 as an NMOS control signal and receives the inverted signal of the second control signal OCCON2 as a PMOS control signal.

The second pull-down driver 223 receives the third control signal OCCON3 and selectively electrically couples the second node N2 to ground based on the third control signal OCCON3. When the third control signal OCCON3 is enabled, the second pull-down driver 223 electrically couples the second node N2 to ground. When the third control signal OCCON3 is disabled, the second pull-down driver 223 isolates the second node N2 from ground. The third pull-down driver 223 may include a second transistor T2. The second transistor T2 may be an N channel MOS transistor. A gate of the second transistor T2 receives the third control signal OCCON3. A drain of the second transistor T2 is electrically coupled to the second node N2. A source of the second transistor T2 is electrically coupled to ground.

The second switching circuit 224 receives the fourth control signal OCCON4 and selectively provides the reference voltage VREF to the second node N2 based on the fourth control signal OCCON4. When the fourth control signal OCCON4 is enabled, the second switching circuit 224 provides the reference voltage VREF to the second node N2. When the fourth control signal OCCON4 is disabled, the second switching circuit 224 does not provide the reference voltage VREF to the second node N2. The second switching circuit 224 includes a second pass gate P2. One end of the second pass gate P2 is electrically coupled to the second node N2. The other end of the second pass gate P2 is provided with the reference voltage VREF. The second pass gate P2 receives the fourth control signal OCCON4 as an NMOS control signal and receives the inverted signal of the fourth control signal OCCON4 as a PMOS control signal.

TABLE 1

| Operation | | | | | |
|---|---|---|---|---|---|
| mode | OCCON<1> | OCCON<2> | OCCON<3> | OCCON<4> | VRCON |
| First | H | H | H | L | Disable |
| mode | | | | | |
| Second | L | H | L | H | Disable |
| mode | | | | | |
| Third | L | H | L | H | Enable |
| mode | | | | | |
| Fourth | H | H | L | H | Enable |
| mode | | | | | |

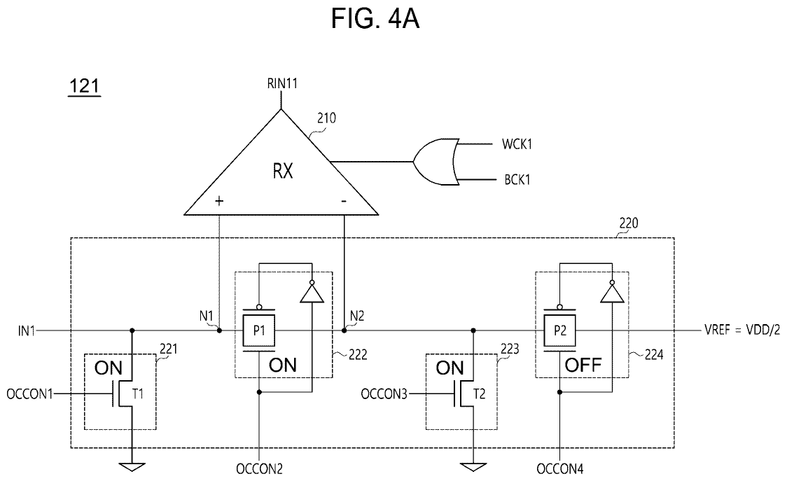

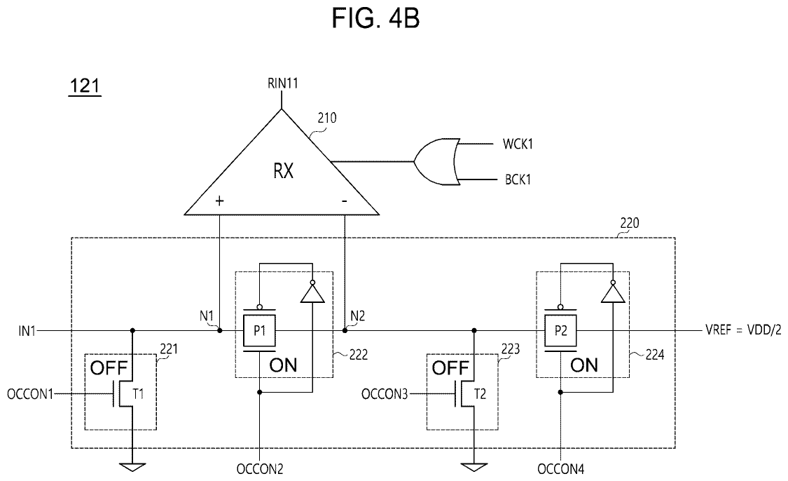

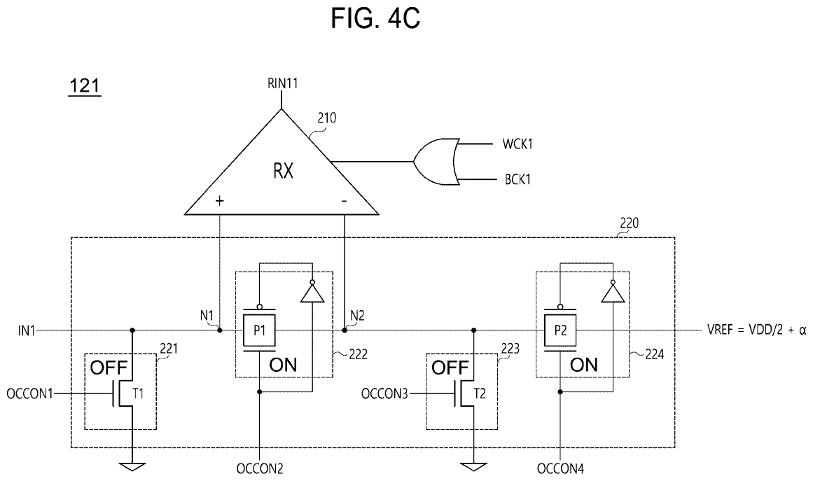

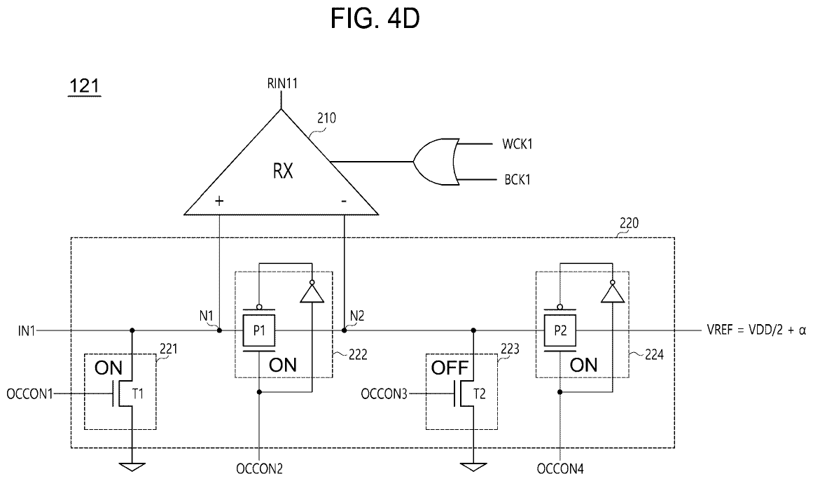

Table 1 is a table illustrating the logic levels of the first control signal OCCON1, the second control signal OCCON2, the third control signal OCCON3, the fourth control signal OCCON4, and the reference voltage control signal VRCON, which are used to select the operation mode as one of the first to fourth modes. FIG. 4A to FIG. 4D are diagrams illustrating the signal states of the first data reception circuit 122-1 according to the operation modes. The operations of the first data reception circuit 122-1 according to an embodiment are described with reference to Table 1, FIG. 1 and FIG. 4A to FIG. 4D.

FIG. 4A illustrates signal states of the first data reception circuit 122-1 during the first mode. To select the first mode as the operation mode, the calibration control circuit 110 enables the control signals OCCON1, OCCON2, and OCCON3 at a logic high level H and disables the fourth control signal OCCON4 at a logic low level L. The calibration control circuit 110 disables the reference voltage control signal VRCON. The reference voltage generation circuits 140, 150, and 160 each generate the reference voltage VREF at a voltage level VDD/2 corresponding to half the source voltage VDD based on the reference voltage control signal VRCON. The first pull-down driver 221 is turned on in response to the first control signal OCCO1 and electrically couples the first node N1 to ground. The first switching circuit 222 is turned on in response to the second control signal OCCON2 and electrically couples the first node N1 to the second node N2. The second pull-down driver 223 is turned on in response to the third control signal OCCON3, and electrically couples the second node N2 to ground. The second switching circuit 224 is turned off in response to the fourth control signal OCCON4 and blocks or isolates the reference voltage VREF from the second node N2. During the first mode, the nodes N1 and N2 are electrically coupled to ground and the nodes N1 and N2 may be electrically coupled. Accordingly, a difference between the voltage levels of the nodes N1 and N2 becomes substantially the same and a difference between the levels of voltages supplied to the first and second input terminals (+,−) of the receiver 210 can be minimized in an embodiment. During the first mode, the first data reception circuit 122-1 can perform the offset calibration more precisely.

FIG. 4B illustrates the signal states of the first data reception circuit 122-1 during the second mode. To select the second mode as the operation mode, the calibration control circuit 110 enables the control signals OCCON2 and OCCON4 at a logic high level H and disables the control signals OCCON1 and OCCON3 at a logic low level L. The calibration control circuit 110 disables the reference voltage control signal VRCON. The reference voltage generation circuits 140, 150, and 160 each generate the reference voltage VREF at a voltage level VDD/2 corresponding to half the source voltage VDD based on the reference voltage control signal VRCON. The first pull-down driver 221 is turned off in response to the first control signal OCCON1 and isolates the first node N1 from ground. The first switching circuit 222 is turned on in response to the second control signal OCCON2 and electrically couples the first node Na to the second node N2. The second pull-down driver 223 is turned off in response to the third control signal OCCON3 and isolates the second node N2 from ground. The second switching circuit 224 is turned on in response to the fourth control signal OCCON4 and provides the reference voltage VREF to the second node N2. During the second mode, the first node N1 is electrically coupled to the second node and the nodes N1 and N2 are provided with the reference voltage VREF. During the first mode, the offset calibration is performed in the when the nodes N1 and N2 are at a voltage level corresponding to ground. During the second mode, the offset calibration is performed when the nodes N1 and N2 are at the voltage level of the reference voltage VREF. During the second mode, the first data reception circuit 122-1 performs offset calibration in an environment close to a level at which the first data signal IN1 varies or swings during normal operation. In an embodiment, a difference between common mode input levels between normal operation and offset calibration operation may be reduced.

FIG. 4C illustrates the signal states of the first data reception circuit 122-1 during the third mode. To select the third mode as the operation mod, the calibration control circuit 110 enables the control signals OCCON2 and OCCON4 at a logic high level H and disables the control signals OCCON1 and OCCON3 at a logic low level L. The calibration control circuit 110 enables the reference voltage control signal VRCON. The reference voltage generation circuits 140, 150, and 160 each generate the reference voltage VREF at a voltage level higher or lower than a voltage level corresponding to half the source voltage VDD based on the reference voltage control signal VRCON. For example, the reference voltage VREF is at a voltage level (VDD/2)+a higher than the voltage level corresponding to half the source voltage VDD. The first pull-down driver 221 is turned off in response to the first control signal OCCON1 and isolates the first node N1 from ground. The first switching circuit 222 is turned on in response to the second control signal OCCON2 and electrically couples the first node N1 to the second node N2. The second pull-down driver 223 is turned off in response to the third control signal OCCON3 and isolates the second node N2 from ground. The second switching circuit 224 is turned on in response to the fourth control signal OCCON4 and provides the reference voltage VREF to the second node N2. During the third mode, the voltage levels of the nodes N1 and N2 are at a specific voltage level, for example, (VDD/2)+a), not the voltage level corresponding to half the source voltage VDD. The first data signal IN1 commonly swings or varies on the basis of the voltage level corresponding to half the source voltage VDD, although the swing range of the first data signal IN1 may vary depending on the type and operating environment of a computing system in which the semiconductor 100 is disposed. During the third mode, the first data reception circuit 122-1 sets the voltage levels of the nodes N1 and N2 at a voltage level corresponding to the middle of a range in which the first data signal IN1 actually swings or varies and performs offset calibration, thus the accuracy of offset calibration operation may be improved in an embodiment.

FIG. 4D illustrates signal states of the first data reception circuit 122-1 during the fourth mode. To select the fourth mode as the operation mode, the calibration control circuit 110 enables the control signals OCCON1, OCCON2, and OCCON4 at a logic high level H and disables the third control signal OCCON3 at a logic low level L. The calibration control circuit 110 enables the reference voltage control signal VRCON. The reference voltage generation circuits 140, 150, and 160 each generate the reference voltage VREF at a voltage level (VDD/2)+a higher than the voltage level corresponding to half the source voltage VDD based on the reference voltage control signal VRCON. The first pull-down driver 221 is turned on in response to the first control signal OCCON1 and electrically couples the first node N1 to ground. The first switching circuit 222 is turned on in response to the second control signal OCCON2 and electrically couples the first node N1 to the second node N2. The second pull-down driver 223 is turned off in response to the third control signal OCCON3 and isolates the second node N2 from ground. The second switching circuit 224 is turned on in response to the fourth control signal OCCON4 and provides the reference voltage VREF to the second node N2. During the fourth mode, the first data reception circuit 122-1 sets the voltage level of the first node N1 different from the voltage level of the second node N2. A difference between the voltage levels of the nodes N1 and N2 is adjusted by changing the voltage level of the reference voltage VREF or changing the current through the first pull-down driver 221. During the fourth mode, the first data reception circuit 122-1 may perform offset calibration after assuming various actual operating environments.

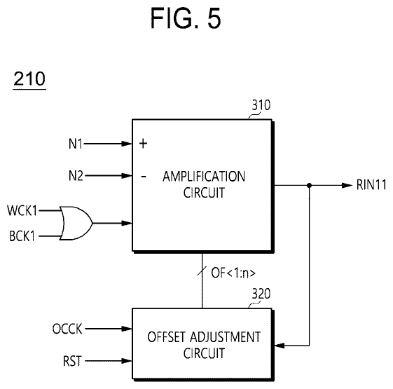

FIG. 5 is a diagram illustrating a construction of the receiver 210, for example, as illustrated in FIG. 3. Referring to FIG. 5, the receiver 210 includes an amplification circuit 310 and an offset adjustment circuit 320. A first input stage (+) of the amplification circuit 310 is electrically coupled to the first node N1. A second input stage (−) of the amplification circuit 310 is electrically coupled to the second node N2. The amplification circuit 310 receives the first write clock signal WCK1 logically combined with the first calibration clock signal BCK1. During normal operation, the amplification circuit 310 generates the first reception signal RIN11 by differentially amplifying the voltage levels at the nodes N1 and N2 in synchronization with the first write clock signal WCK1. During the offset calibration operation, the amplification circuit 310 generates the first reception signal RIN11 by differentially amplifying the voltage levels of the nodes N1 and N2 in synchronization with the first calibration clock signal BCK1. The amplification circuit 310 receive an offset adjustment signal OF<1:n>. In this example, n is an integer equal to or greater than 2. The amplification circuit 310 adjusts, based on the offset adjustment signal OF<1:n>, a first current and/or a first current driving force that responds to the voltage level at the first node N1 and a second current and/or a second current driving force that responds to the voltage level at the second node N2. The first current and/or the first current driving force includes a current and/or a current driving force that increases the voltage level of the first reception signal RIN11 based on the voltage level of the first node N1. The second current and/or the second current driving force includes a current and/or a current driving force that decreases the voltage level of the first reception signal RIN11 based on the voltage level of the second node N2. The offset adjustment signal OF<1:n> may be a digital signal including a plurality of bits. For example, when the offset adjustment signal OF<1:n> includes a middle or intermediate logic value, the second current is the same as the first current. As the logic value of the offset adjustment signal OF<1:n> increases from the middle logic value, the second current increases. As the logic value of the offset adjustment signal OF<1:n> decreases from the middle logic value, the first current increases.

The offset adjustment circuit 320 receives the first reception signal RIN11 and the first calibration clock signal BCK1 and generates the offset adjustment signal OF<1:n> based on the first reception signal RIN11 and the first calibration clock signal BCK1. The offset adjustment circuit 320 counts a characteristic, such as a rising or falling edge, of the first calibration clock signal BCK1 and decreases the logic value of the offset adjustment signal OF<1:n> whenever the offset adjustment circuit 320 counts the characteristic of the first calibration clock signal BCK1. For example, the offset adjustment circuit 320 decreases the logic value of the offset adjustment signal OF<1:n> by 1 whenever the offset adjustment circuit 320 counts a falling edge of the first calibration clock signal BCK1. The offset adjustment circuit 320 decreases the logic value of the offset adjustment signal OF<1:n> whenever the offset adjustment circuit 320 counts the characteristic of the first calibration clock signal BCK1 when the logic value of the first reception signal RIN11 is a first logic level. The offset adjustment circuit 320 maintains the logic value of the offset adjustment signal OF<1:n> without decreasing the logic value of the offset adjustment signal OF<1:n> when the logic value of the first reception signal RIN11 is a second logic level. The offset adjustment circuit 320 receives a reset signal RST. The offset adjustment circuit 320 sets the logic value of the offset adjustment signal OF<1:n> as a default value based on the reset signal RST. For example, the default value of the offset adjustment signal OF<1:n> may be an upper value of the offset adjustment signal OF<1:n>. The reset signal RST includes a signal that is generated when the semiconductor apparatus 100 of FIG. 1 is powered up or when the semiconductor apparatus 100 receives the command address signal CA indicating or initiating execution of the offset calibration operation.

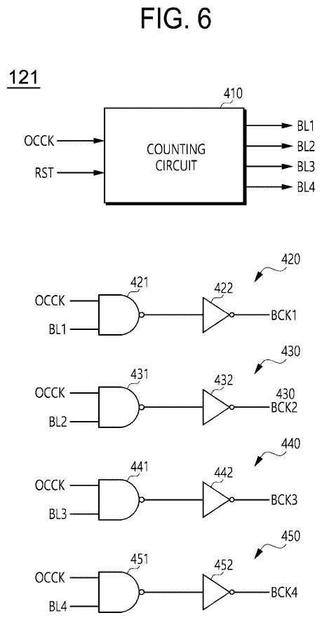

FIG. 6 is a diagram illustrating a construction of the calibration clock generation circuit 121 according to an embodiment. Referring to FIG. 6, the calibration clock generation circuit 121 includes a counting circuit 410, a first clock gating circuit 420, a second clock gating circuit 430, a third clock gating circuit 440, and a fourth clock gating circuit 450. The counting circuit 410 generates a first enable signal BL1, a second enable signal BL2, a third enable signal BL3, and a fourth enable signal BL4 based on a reset signal RST and the main clock signal OCCK. The reset signal RST may be the same signal as the reset signal RST of FIG. 5. When the reset signal RST is enabled, the counting circuit 410 enables the first enable signal BL1 and maintains the enable signals BL2, BL3, and BL4 in the disabled state. The counting circuit 410 sequentially enables the enable signals BL2, BL3, and BL4 while a characteristic of the main clock signal OCCK is counted by a predetermined quantity, which characteristic may be a rising edge or a falling edge. The predetermined quantity may be, for example, 7 or another quantity. After the reset signal RST is enabled, when the main clock signal OCCK is toggled or cycled seven times, the counting circuit 410 enables the second enable signal BL2 and disables the first enable signal BL1. After the second enable signal BL2 is enabled, while the main clock signal OCCK is toggled or cycled seven times, the counting circuit 410 enables the third enable signal BL3 and disables the second enable signal BL2. After the third enable signal BL3 is enabled, while the main clock signal OCCK is toggled seven times, the counting circuit 410 enables the fourth enable signal BL4 and disables the third enable signal BL3. After the fourth enable signal BL4 is enabled, while the main clock signal OCCK is toggled or cycled seven times, the counting circuit 410 disables the fourth enable signal BL4.

The first clock gating circuit 420 receives the main clock signal OCCK and the first enable signal BL1 and generates the first calibration clock signal BCK1 by gating the main clock signal OCCK and the first enable signal BL1. When the first enable signal BL1 is enabled, the first clock gating circuit 420 outputs the main clock signal OCCK as the first calibration clock signal BCK1. The first clock gating circuit 420 includes a first NAND gate 421 and a first inverter 422. The first NAND gate 421 receives the main clock signal OCCK and the first enable signal BL1. The first inverter 422 outputs the first calibration clock signal BCK1 by inverting and driving the output signal of the first NAND gate 421.

The second clock gating circuit 430 receives the main clock signal OCCK and the second enable signal BL2 and generates the second calibration clock signal BCK2 by gating the main clock signal OCCK and the second enable signal BL2. When the second enable signal BL2 is enabled, the second clock gating circuit 430 outputs the main clock signal OCCK as the second calibration clock signal BCK2. The second clock gating circuit 430 includes a second NAND gate 431 and a second inverter 432. The second NAND gate 431 receives the main clock signal OCCK and the second enable signal BL2. The second inverter 432 outputs the second calibration clock signal BCK2 by inverting and driving the output signal of the second NAND gate 431.

The third clock gating circuit 440 receives the main clock signal OCCK and the third enable signal BL3 and generates the third calibration clock signal BCK3 by gating the main clock signal OCCK and the third enable signal BL3. When the third enable signal BL3 is enabled, the third clock gating circuit 440 outputs the main clock signal OCCK as the third calibration clock signal BCK3. The third clock gating circuit 440 includes a third NAND gate 441 and a third inverter 442. The third NAND gate 441 receives the main clock signal OCCK and the third enable signal BL3. The third inverter 442 outputs the third calibration clock signal BCK3 by inverting and driving the output signal of the third NAND gate 441.

The fourth clock gating circuit 450 receives the main clock signal OCCK and the fourth enable signal BL4 and generates the fourth calibration clock signal BCK4 by gating the main clock signal OCCK and the fourth enable signal BL4. When the fourth enable signal BL4 is enabled, the fourth clock gating circuit 450 outputs the main clock signal OCCK as the fourth calibration clock signal BCK4. The fourth clock gating circuit 450 includes a fourth NAND gate 451 and a fourth inverter 452. The fourth NAND gate 451 receives the main clock signal OCCK and the fourth enable signal BL4. The fourth inverter 452 outputs the fourth calibration clock signal BCK4 by inverting and driving the output signal of the fourth NAND gate 451.

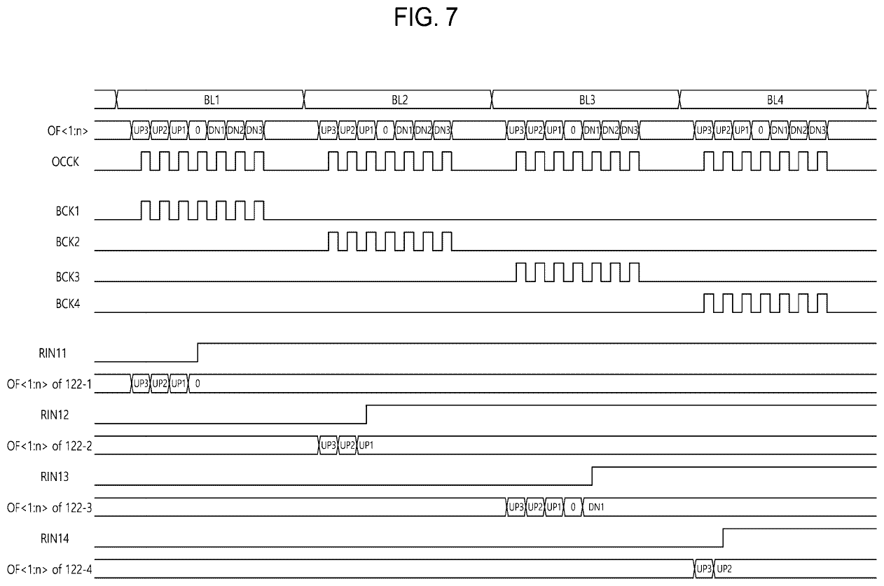

FIG. 7 is a timing diagram illustrating offset calibration operation of the semiconductor apparatus 100 according to an embodiment. Operation of the semiconductor apparatus 100 according to an embodiment is described as follows with reference to FIG. 1 to FIG. 7. When receiving, from the external device, the command address signal CA indicating or initiating execution of the offset calibration operation, the command address control circuit 170 generates the offset calibration signal OCAL and provides the offset calibration signal OCAL to the calibration control circuit 110. The calibration control circuit 110 generate the main clock signal OCCK based on the offset calibration signal OCAL and generates the calibration control signal OCCON that selects the operation mode of the data reception circuits of each of the data input and output blocks 120 and 130 as one of the first to fourth modes. The calibration control circuit 110 generates the reference voltage control signal VRCON depending on the operation mode. For example, when the operation mode is the first mode, the calibration control circuit 110 enable the control signals OCCON1, OCCON2, and OCCON3 and disables the fourth control signal OCCON4 and the reference voltage control signal VRCON. The calibration control circuit 110 sequentially performs offset calibration operations of the data input and output blocks 120 and 130. The calibration control circuit 110 may first perform offset calibration operation on the first data input and output block 120 and may perform offset calibration operation on the second data input and output block 130 after the offset calibration operation on the first data input and output block 120 is completed. To sequentially perform offset calibration operations on the input and output blocks 120 and 130, the calibration control circuit 110 activates the calibration clock generation circuit 121 of the first data input and output block 120 and subsequently activates the calibration clock generation circuit 131 of the second data input and output block 130.

The calibration clock generation circuit 121 sequentially generates the calibration clock signals BCK1, BCK2, BCK3, and BCK4 based on the reset signal RST and the main clock signal OCCK. The calibration clock generation circuit 121 sequentially enables the enable signals BL1, BL2, BL3, and BL4 by counting a characteristic of the main clock signal OCCK, for example, seven times. The calibration clock signals BCK1, BCK2, BCK3, and BCK4 may each be sequentially toggled or cycled seven times. The data reception circuits 122-1, 122-2, 122-3, and 122-4 sequentially perform offset calibration based on the calibration clock signals BCK1, BCK2, BCK3, and BCK4, respectively. In the example of FIG. 7, an upper value of the offset adjustment signal OF<1:n> is indicated as UP3, a middle value of the offset adjustment signal OF<1:n> is indicated as 0, and a minimum value of the offset adjustment signal OF<1:n> is indicated as DN3. A value that is one value lower than UP3 is indicated as UP2. A value that is one value higher than the middle value is indicated as UP1. A value that is one value lower than the middle value is indicated as DN1. A value that is one value higher than DN3 is indicated as DN2.

While the first calibration clock signal BCK1 is toggled or cycled, offset calibration of the first data reception circuit 122-1 is performed. While the first calibration clock signal BCK1 is toggled, the first data reception circuit 122-1 decreases the value of the offset adjustment signal OF<1:n> until the first reception signal RIN11 changes from the first logic level to the second logic level. For example, when the first reception signal RIN11 at the second logic level is generated when the offset adjustment signal <OF<1:n> is at the middle value, the first data reception circuit 122-1 maintains the logic value of the offset adjustment signal OF<1:n> at the middle value.

After the first calibration clock signal BCK1 is toggled seven times, the second calibration clock signal BCK2 is toggled or cycled, and offset calibration of the second data reception circuit 122-2 is performed. While the second calibration clock signal BCK2 is toggled, the second data reception circuit 122-2 decreases the value of the offset adjustment signal OF<1:n> until the second reception signal RIN12 changes from the first logic level to the second logic level. For example, when the second reception signal RIN12 at the second logic level is generated when the offset adjustment signal OF<1:n> is at a value corresponding to UP1, the second data reception circuit 122-2 maintains the logic value of the offset adjustment signal OF<1:n> at the value corresponding to UP1.

After the second calibration clock signal BCK2 is toggled seven times, the third calibration clock signal BCK3 is toggled or cycled, and offset calibration of the third data reception circuit 122-3 is performed. While the third calibration clock signal BCK3 is toggled, the third data reception circuit 122-3 decreases the value of the offset adjustment signal OF<1:n> until the third reception signal RIN13 changes from the first logic level to the second logic level. For example, when the third reception signal RIN13 at the second logic level is generated when the offset adjustment signal OF<1:n> is at a value corresponding to DN1, the third data reception circuit 122-3 maintains the logic value of the offset adjustment signal OF<1:n> to the value corresponding to DN1.

After the third calibration clock signal BCK3 is toggled seven times, the fourth calibration clock signal BCK4 is toggled or cycled, and offset calibration of the fourth data reception circuit 122-4 is performed. While the fourth calibration clock signal BCK4 is toggled, the fourth data reception circuit 122-4 decreases the value of the offset adjustment signal OF<1:n> until the fourth reception signal RIN14 changes from the first logic level to the second logic level. For example, when the fourth reception signal RIN4 at the second logic level is generated when the offset adjustment signal OF<1:n> is at a value corresponding to UP2, the fourth data reception circuit 122-4 maintains the logic value of the offset adjustment signal OF<1:n> to the value corresponding to UP2.

According to an embodiment, the current generated by the data reception circuits 122-1, 122-2, 122-3, and 122-4 may independently compensate for process variation and a transistor mismatch. The data reception circuits 122-1, 122-2, 122-3, and 122-4 may each perform normal operation in the state in which the offset of each of the data reception circuits 122-1, 122-2, 122-3, and 122-4 is calibrated by the offset adjustment signal OF<1:n>.

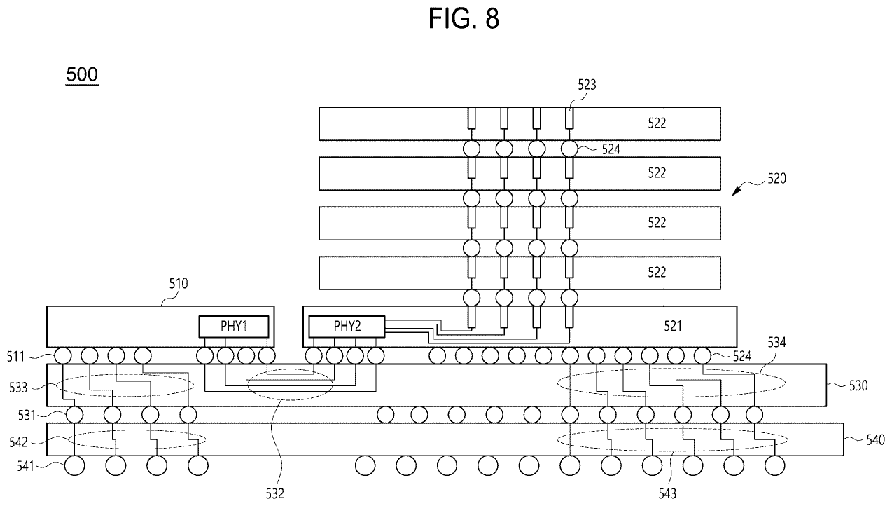

FIG. 8 is a diagram illustrating a construction of a semiconductor system 500 according to an embodiment. Referring to FIG. 8, the semiconductor system 500 includes a host device 510 and a memory device 520. The host device 510 is a master device that controls the memory device 520 such that the memory device 520 performs various operations. The host device 510 accesses the memory device 520 and writes data in the memory device 520 during a write operation and reads data stored in the memory device 520 during a read operation. For example, the host device 510 includes at least one of a central processing unit (CPU), a graphic processing unit (GPU), a multi-media processor (MMP), a digital signal processor (DSP), an application processor (AP), a data processing unit (DPU), a neural processing unit (NPU), a system-on-chip (SoC), and so forth. The memory device 520 is controlled by the host device 510 and stores data transmitted by the host device 510 and outputs, to the host device 510, data stored in the memory device 520. For example, the memory device 520 may be a high bandwidth memory (HBM) device.

The host device 510 includes an interface circuit PHY1. The host device 510 is electrically coupled to the memory device 520 through the interface circuit PHY1 and transmits various signals to the memory device 520 through the interface circuit PHY1 and receives various signals from the memory device 520. The host device 510 is a component corresponding to the external device. For example, the host device 510 transmits the command address signal CA, a system clock signal pair, a data clock signal pair, strobe signals, and data to the memory device 520 through the interface circuit PHY1 and receives strobe signals and data transmitted by the memory device 520 through the interface circuit PHY1. The memory device 520 includes a logic die 521 and a plurality of memory dies 522. The plurality of memory dies 522 is sequentially stacked over the logic die 521 and is electrically coupled through through vias 523 that are formed through the logic die 521 and the plurality of memory dies 522. The logic die 521 relays data communicated between the host device 510 and the plurality of memory dies 522. The logic die 521 includes an interface circuit PHY2 that electrically couples the host device 510 and the plurality of memory dies 522. The interface circuit PHY2 converts a signal that is transmitted by the host device 510 into a signal that is suitable for use in the memory device 520 and transmits the converted signal to the plurality of memory dies 522. The interface circuit PHY2 converts a signal that is output by the plurality of memory dies 522 into a signal that is suitable for use in the host device 510 and transmits the converted signal to the host device 510. The interface circuit PHY2 of the logic die 521 includes the components of the semiconductor apparatus 100 illustrated in FIG. 1. To support high bandwidth, the memory device 520 is electrically coupled to the host device 510 through a large quantity of signal transmission lines or conductors. Accordingly, the memory device 520 may be manufactured in a form in which the memory device 520 and the host device 510 are stacked on a single substrate.

The semiconductor system 500 includes an interposer 530 and a package substrate 540. The interposer 530 is stacked over the package substrate 540. The host device 510 and the memory device 520 are stacked over the interposer 530. The host device 510 is stacked in a first region, such as a left region in FIG. 8, of the interposer 530. The memory device 520 is stacked in a second region, such as a right region in FIG. 8, of the interposer 530. The package substrate 540, the interposer 530, the host device 510, and the memory device 520 are packaged in a single package in this example. The package substrate 540 is electrically coupled to the external device through package balls 541 also referred to as a ball grid array. Signal paths 542 and 543 that electrically couple the interposer 530 to the package balls 541 are formed in the package substrate 540. The interposer 530 is electrically coupled to the signal paths 542 and 543 of the package substrate 540 through bumps 531.

Signal paths 532 that electrically couple the host device 510 and the memory device 520 are formed in the interposer 530. The signal paths 532 electrically couple the interface circuit PHY2 of the logic die 521 and the interface circuit PHY1 of the host device 510. Signal paths 533 and 534 that electrically couple the host device 510 and the memory device 520 to the package substrate 540 are formed in the interposer 530. The host device 510 is electrically coupled to the signal paths 533 of the interposer 530 through micro bumps 511. The memory device 520 is electrically coupled to the signal paths 534 of the interposer 530 through the micro bumps 524. The logic die 521 is electrically coupled to the signal paths 534 of the interposer 530 through micro bumps 524. The plurality of memory dies 522 is sequentially stacked over the logic die 521 using the micro bumps 524. The micro bumps 524 electrically couple the through vias of the logic die 521 and through vias between the plurality of memory dies 522. The signal paths 532 of the interposer 530, which electrically couples the interface circuits PHY2 and PHY1 of the logic die 521 and the host device 510, may be any combination of a signal transmission line, a link, a bus, a conductor, or a channel between the host device 510 and the memory device 520. For example, the command address signal CA and the data signals IN1 and IN2 of in FIG. 1 are transmitted between the host device 510 and the memory device 520 through the signal paths 532. The signal paths 533 of the interposer 530, which electrically couple the host device 510 and the package substrate 540, may be any combination of a signal transmission line, a link, a bus, a conductor, or a channel used for communication between the host device 510 and the external device. The signal paths 534 of the interposer 530, which electrically couple the logic die 521 and the package substrate 540, may be direct access paths along which the external device directly access the memory device 520.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A semiconductor apparatus comprising:
a calibration control circuit configured to generate a main clock signal, a calibration control signal, and a reference voltage control signal based on an offset calibration signal;
a first data input and output block configured to generate a first group of reception signals based on a first data signal and a reference voltage and configured to adjust an offset of the first data input and output block based on the main clock signal and the calibration control signal;
a second data input and output block, configured to generate a second group of reception signals based on a second data signal and the reference voltage and configured to adjust an offset of the second data input and output block based on the main clock signal and the calibration control signal;
a first reference voltage generation circuit configured to generate the reference voltage based on the reference voltage control signal;
a second reference voltage generation circuit configured to generate the reference voltage based on the reference voltage control signal; and
a third reference voltage generation circuit configured to generate the reference voltage based on the reference voltage control signal.

2. The semiconductor apparatus of claim 1, wherein the first data input and output block comprises:
a calibration clock generation circuit configured to receive the main clock signal to generate a first calibration clock signal and a second calibration clock signal;
a first data reception circuit configured to generate a first reception signal by comparing the first data signal and the reference voltage based on the calibration control signal and the first calibration clock signal and configured to adjust the offset based on the first reception signal; and
a second data reception circuit configured to generate a second reception signal by comparing the first data signal and the reference voltage based on the calibration control signal and the second calibration clock signal and configured to adjust the offset based on the second reception signal.

3. The semiconductor apparatus of claim 2, wherein the calibration clock generation circuit is configured to count a characteristic of the main clock signal and sequentially output the first and the second calibration clock signals based on the count.

4. The semiconductor apparatus of claim 2, wherein the calibration clock generation circuit comprises:
a counting circuit configured to generate a first enable signal and a second enable signal based on a reset signal and the main clock signal;
a first clock gating circuit configured to output the first calibration clock signal by gating the main clock signal and the first enable signal; and
a second clock gating circuit configured to output the second calibration clock signal by gating the main clock signal and the second enable signal.

5. The semiconductor apparatus of claim 4, wherein the counting circuit is configured to generate a first enable signal based on the reset signal, disable the first enable signal and enable the second enable signal while a characteristic of the main clock signal is counted by a predetermined quantity, and subsequently disable the second enable signal while the main clock signal is counted by the predetermined quantity.

6. The semiconductor apparatus of claim 1, wherein the reference voltage output by the first reference voltage generation circuit, the second reference voltage generation circuit, and the third reference voltage generation circuit is supplied to the first data input and output block and the second data input and output block using a single power line.

7. The semiconductor apparatus of claim 1, wherein each of the first reference voltage generation circuit, the second reference voltage generation circuit, and the third reference voltage generation circuit is configured to generate the reference voltage at a voltage level at a middle voltage of a range of the first data signal and the second data signal while the reference voltage control signal is disabled and generate the reference voltage at a voltage level different from the voltage level corresponding to the middle voltage when the reference voltage control signal is enabled.

8. The semiconductor apparatus of claim 1, wherein the calibration control circuit and the first reference voltage generation circuit are disposed in the first region, wherein the first data input and output block and the second reference voltage generation circuit are disposed in the second region, and wherein the second data input and output block and the third reference voltage generation circuit are disposed in the third region.

9. The semiconductor apparatus of claim 8, wherein:
the second region is adjacent to a first side of the first region, and
the third region is adjacent to a second side of the first region.

10. A semiconductor apparatus comprising:
a data reception circuit configured to generate a reception signal by comparing a data signal and a reference voltage based on a calibration clock signal; and
a reference voltage generation circuit configured to generate the reference voltage at different voltage levels based on an operation mode;
wherein the data reception circuit comprises:
a first node on which the data signal is input;
a second node;
a receiver configured to generate the reception signal by differentially amplifying a voltage level of the first node and a voltage level of the second node in synchronization with the calibration clock signal; and
a calibration setting circuit configured to selectively electrically couple the first node to ground, to selectively electrically couple the first node to the second node, to selectively electrically couple the second node to ground, and to selectively provide the reference voltage to the second node based on the operation mode.

11. The semiconductor apparatus of claim 10, wherein:
when the operation mode is a first mode, the calibration setting circuit electrically couples the first node to ground, electrically couples the first node to the second node, electrically couples the second node to ground, and isolates the reference voltage from the second node; and
the reference voltage generation circuit generates the reference voltage at a first voltage level.

12. The semiconductor apparatus of claim 10, wherein:
when the operation mode is a second mode, the calibration setting circuit isolates the first node from ground, electrically couples the first node to the second node, isolates the second node from ground, and provides the reference voltage to the second node; and
the reference voltage generation circuit generates the reference voltage at a first voltage level.

13. The semiconductor apparatus of claim 10, wherein:
when the operation mode is a third mode, the calibration setting circuit isolates the first node from ground, electrically couples the first node to the second node, isolates the second node from ground, and provides the reference voltage to the second node; and
the reference voltage generation circuit generates the reference voltage at a second voltage level.

14. The semiconductor apparatus of claim 10, wherein:
when the operation mode is a fourth mode, the calibration setting circuit electrically couples the first node to ground, electrically couples the first node to the second node, isolates the second node from ground, and provides the reference voltage to the second node; and
the reference voltage generation circuit generates the reference voltage at a second voltage level.

15. The semiconductor apparatus of claim 10, wherein the reference voltage generation circuit is configured to generate the reference voltage at one of a first voltage level and a second voltage level based on a reference voltage control signal.

16. The semiconductor apparatus of claim 15, wherein:
the first voltage level is a voltage level corresponding to a middle voltage of a range in which the data signal varies; and
the second voltage level is higher or lower than the first voltage level.

17. The semiconductor apparatus of claim 10, wherein the receiver comprises:
an amplification circuit configured to generate the reception signal by differentially amplifying the voltage levels of the first and second nodes in synchronization with the calibration clock signal and configured to adjust a current that responds to the voltage level of the first node and a current that responds to the voltage level of the second node based on an offset adjustment signal; and
an offset adjustment circuit configured to generate an offset adjustment signal based on the calibration clock signal and the reception signal.

18. The semiconductor apparatus of claim 17, wherein the offset adjustment circuit is configured to decrease a logic value of the offset adjustment signal from a default value by counting a characteristic of the calibration clock signal when the reception signal is at a first logic level and to maintain a logic value of the offset adjustment signal when the reception signal is at a second logic level.

19. The semiconductor apparatus of claim 10, wherein the calibration setting circuit comprises:
a first pull-down driver configured to selectively electrically couple the first node to ground based on a first control signal;
a first switching circuit configured to selectively electrically couple the first node to the second node based on a second control signal;
a second pull-down driver configured to selectively electrically couple the second node to ground based on a third control signal; and
a second switching circuit configured to selectively provide the reference voltage to the second node based on a fourth control signal.

20. A semiconductor comprising:
a reference voltage generation circuit configured to generate the reference voltage at a voltage level based on an operation mode; and
a data reception circuit comprising:
a receiver configured to generate a reception signal, in synchronization with a calibration clock signal, by differentially amplifying a voltage level of a second node and a voltage level of a first node coupled to a data signal; and
a calibration setting circuit configured to, based on the operation mode, selectively couple the first node to at least one of ground and the second node and selectively couple the second node to one of ground and the reference voltage.
